(19) United States
(12) Patent Application Publication
(10) Pub. No.: US 2006/0098396 A1
(43) Pub. Date: May 11, 2006

(54) Communication module

(75) Inventor: Cheng-Yen Shih, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/256,088

(22) Filed: Oct. 24, 2005

(30) Foreign Application Priority Data
Oct. 26, 2004 (TW) 93132454

(51) Int. Cl. H05K 5/00

(52) U.S. Cl. 361/679

(57) ABSTRACT

A communication module. The communication module comprises at least one supporting structure, at least one first electronic component, and at least one connecting pad. The supporting structure comprises a first surface and a hollow portion. The first electronic component is disposed in the hollow portion. The connecting pad is disposed on the first surface and electrically connected to the first electronic component.

### BACKGROUND

The invention relates to a communication module, and in particular to a Bluetooth module.

In wireless communication systems, Bluetooth communication protocol is a rapidly developing technology, of which the most important element is the Bluetooth module.

Passive components such as inductors, resistors, and capacitors and active components such as Bluetooth chips and oscillators, crystals are disposed at a side of a ceramic supporting structure to constitute a Bluetooth module. Connecting wires of each element passing through the interior of the ceramic supporting structure are connected to a circuit board at another side of the ceramic supporting structure. To prevent electromagnetic interference (EMI) leakage from the elements, they must be covered with a shielded metal layer. However, the system requires many elements, each of which is separately manufactured and disposed on the ceramic supporting structure. Thus, the volume of the Bluetooth module is restricted by the size of each element.

Since communication products are required to be as compact as possible, and the volume of the conventional Bluetooth module cannot be further reduced, final product requirements are difficult to satisfy. To solve this problem, reduced-size high frequency module packages such as system-in-package (SIP) and system-on-package (SOP) formats have been introduced.

The system-on-package is integrated with embedded passive technology. Components such as semiconductors and other external passive elements are disposed on a surface of the supporting structure by surface-mounting or die-bonding. The elements on the surface of the supporting structure are covered with a shielding case layer to reduce EMI leakage. The advantage is that volume is reduced with maintained reliability; however, the cost of the supporting structure is high.

The system-in-package is integrated with embedded active technology such as micro-electromechanical system (MEMS), chip on chip, or multi-chip assembly to integrate active components, and passive components are integrated into a single package with the shielding case layer reducing EMI leakage. Although reduced volume and low costs are provided, the assembly is difficult and reliability is not assured.

In the described technology, as elements and connecting pads are on the opposite sides, circuits must pass through the substrate to electrically connect to a main system. This requires high technology, takes much time, and the modules occupy more space.

### SUMMARY

Embodiments of the invention provide a communication module to eliminate the shortcomings of conventional design such that the size of the communication module is as compact as possible with low manufacturing costs and easier assembly.

Embodiments of the invention provide a communication module comprising at least one supporting structure, at least one first electronic component, and at least one connecting pad. The supporting structure comprises a first surface and a hollow portion. The first electronic component is disposed in the hollow portion. The connecting pad is disposed on the first surface and electrically connected to the first electronic component.

The connecting pad and the first electronic component are disposed on the same side. The connecting pad is disposed on the supporting structure at a position higher than the first electronic component. The connecting pad is a surface mounting pad or a die-bonding pad. The first electronic component includes at least one active component, passive component, or both. The active component includes Bluetooth chips, memory chips, or a combination thereof. The passive component includes oscillators, crystals, filters, unbalanced to balanced converters, inductors, capacitors, resistors, or a combination thereof. Additionally, the first electronic component can comprise both active and passive components.

The communication module further comprises at least one circuit line, embedded in the supporting structure and connecting the connecting pad and the first electronic component. The communication module further comprises a filling material for covering the first electronic component. The filling material partially or fully fills the hollow portion. The filling material comprises glue, sealant, packaging materials, paint, plastic, or a combination thereof.

The communication module further comprises a second electronic component, disposed in the hollow portion or on a second surface of the supporting structure. The second surface corresponds to the first surface. The communication module further comprises a shielding layer embedded in or disposed on the supporting structure, and the shielding layer can be a conductive layer or connected to ground.

The supporting structure is ceramic, low dielectric constant material, glass fiber, organic compound, or a combination thereof. The supporting structure further comprises a first substrate, surrounding the hollow portion and having the first surface, and a second substrate, disposed under the first substrate, wherein a bottom surface of the hollow portion is a partial surface of the second substrate. The first substrate and second substrate are ceramic, low dielectric constant material, glass fiber, organic compound, or a combination thereof. In addition, the second substrate further comprises a circuit line, embedded therein and connecting the connecting pad and the first electronic component.

The communication module further comprises at least one second electronic component and at least one connecting structure. The second electronic component is disposed on the first surface and electrically connected to the connecting pad. The hollow portion is covered with the second electronic component. The connecting structure is disposed on a second surface of the supporting structure and connected to the first electronic component and the second electronic component. The communication module further comprises a circuit board, embedded in the supporting structure and connected to the first electronic component. Moreover, the circuit board comprises at least one passive component.

The communication module is a Bluetooth module. The connecting pad electrically connects the first electronic component to other devices.

Embodiments of the invention further provide a communication module comprising a supporting structure, a first electronic component, a second electronic component, a first connecting pad, and second connecting pad. The supporting structure comprises a first surface, a second surface and at least one hollow portion. The first surface and the hollow portion are disposed on the same side. The first electronic component is disposed in the hollow portion. The second electronic component is disposed on the first surface, and covers the hollow portion. The first connecting pad is disposed on the first surface, electrically connecting the first electronic component and the second electronic component. The second connecting pad is disposed on the second surface, electrically connecting the first electronic component and the second electronic component for electrical connection to other devices. The second electronic component comprises a oscillator or crystal.

Since elements of the communication module are embedded in the hollow portion of the supporting structure, and the connecting pad is higher than the electronic components on the same side, the circuit lines thereof do not penetrate the supporting structure to connect to other devices via the connecting pad at the same side. Thus, the volume of the communication module is significantly reduced.

Additionally, since the electronic components and the connecting pad are on the same side of the supporting structure, the circuit lines therein do not penetrate the supporting structure. Thus, complexity of the circuits is reduced. Difficulties of process, time, and manufacturing costs are thus reduced.

In the communication module of the invention, the oscillator or crystal is disposed on the supporting structure and covers electronic components such as Bluetooth chips and memory chips. The metal surface of oscillator or crystal acts as an EMI shield such that the invention does not require extra shielding from a metal layer, thereby reducing manufacturing costs.

### BRIEF DESCRIPTION OF THE DRAWINGS

Embodiments of the invention can be more fully understood by reading the subsequent detailed description in conjunction with the examples and references made to the accompanying drawings, wherein:

FIG. 1A is a schematic view of an embodiment of a communication module of the invention;

FIG. 1B is a schematic view of the communication module of FIG. 1A with filling material formed therein;

FIG. 1C is a schematic view showing a passive component formed on another surface of the communication module of FIG. 1A;

FIG. 2A is a schematic view of another embodiment of a communication module of the invention;

FIG. 2B is a schematic view of the communication module of FIG. 2A not showing a crystal;

FIG. 2C is a schematic view showing a connecting structure formed on another surface of the communication module of FIG. 2A.

### DETAILED DESCRIPTION

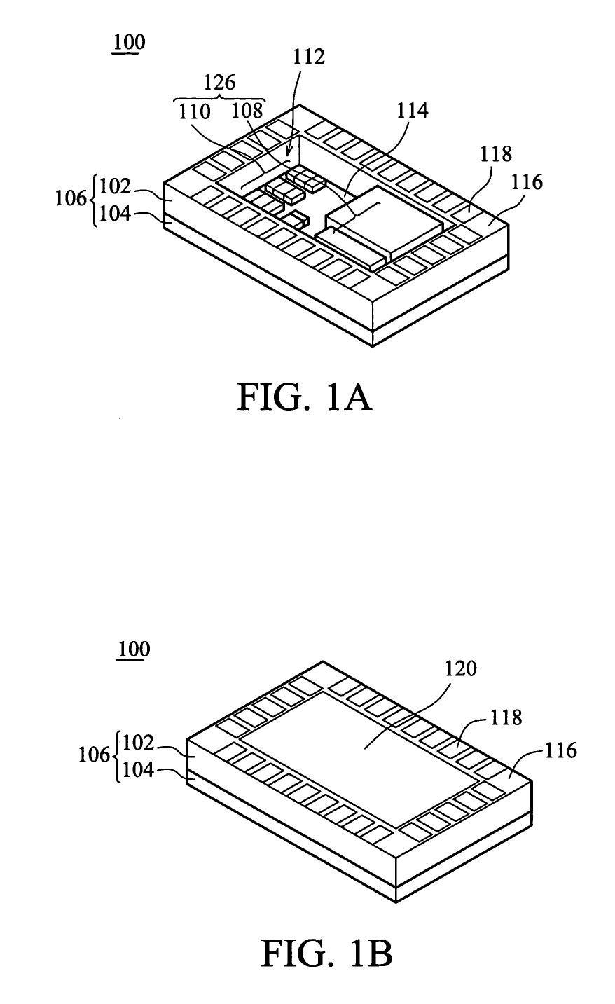

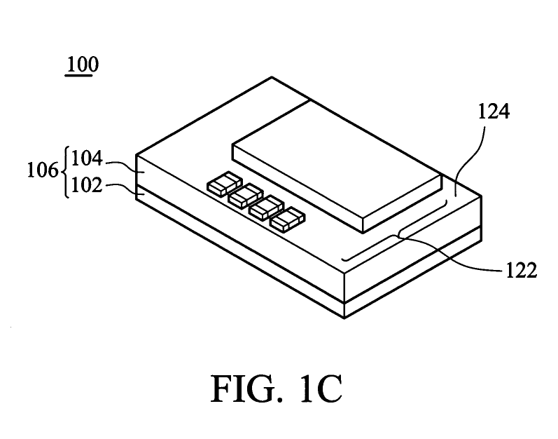

FIG. 1A is a schematic view of an embodiment of a communication module 100 of the invention. FIG. 1B is a schematic view of the communication module 100 of FIG. 1A with filling material 120 formed therein. FIG. 1C is a schematic view showing a passive component 122 formed on another surface 124 of the communication module 100 of FIG. 1A. As shown, the communication module 100 comprises a supporting structure 106, at least one electronic component 126, and at least one connecting pad 118. The supporting structure 106 comprises a surface 116 and a hollow portion 112 formed therein. The electronic component 126 is disposed in the hollow portion 112. The connecting pad 118 is disposed on the surface 116, not in the hollow portion 112, and connected to the electronic component 126. The communication module is Bluetooth module, wireless module, or cable communication module.

The supporting structure 106 is a structure comprising the hollow portion 112. The supporting structure 106 is formed by a single material or a plurality of materials. The supporting structure 106 is formed by a ceramic, a low dielectric constant material, a glass fiber, an organic compound, or a combination thereof.

The supporting structure 106 can be formed by at least two substrates 102 and 104. The first substrate 102, surrounding the hollow portion 112, comprises a first surface 116. The second substrate 104 is disposed under the first substrate 102, and a bottom surface 114 of the hollow portion 112 is a partial surface of the second substrate 104. The substrates 102 and 104 are formed by a ceramic, a low dielectric constant material, a glass fiber, an organic compound, or a combination thereof. The substrates 102 and 104 are formed by the same materials or the different materials. For example, in an embodiment, the substrate 102 is formed by a glass fiber and the substrate 104 is formed by a ceramic. When the supporting structure 106 is constructed of two substrates 102 and 104, circuit lines connecting the electronic component 126 and the connecting pad 118 are directly embedded in the bottom substrate 104.

In addition, the supporting structure 106 may comprise an embedded shielding layer (not shown), a circuit board (not shown), passive components, or a combination thereof. When the communication module 100 is connected to other devices, the shielding layer of the supporting structure 106 effectively prevents EMI. The shielding layer comprises conductive layer or ground layer. The shielding layer may or may not connect to ground. The circuit board is embedded in the supporting structure 106 or exposed, electrically connecting to the electronic component 126. The passive component embedded in the supporting structure 106 can be directly integrated in the circuit board, or electrically connected to the electronic component 126 or the connecting pad 118.

The electronic component 126 is directly disposed in the hollow portion 112 of the supporting structure 106. Circuit lines (not shown), embedded in the supporting structure 106, are electrically connected to the connecting pad 118 without penetrating the supporting structure 106. Since the circuit line connects from the electronic component 126 via the supporting structure 106 to directly connect the connecting pad 118 on the same side, the circuit design is simplified. Moreover, the circuit can circumvent the electronic component 126.

The electronic component 126 can include an active component 108, a passive component 110, or both. The active component 108 includes Bluetooth chips, memory, or a combination thereof. The passive component 110 includes oscillators, crystals, filters, unbalanced to balanced converters, inductors, capacitors, resistors, or a combination thereof. The connecting pad 118 is disposed on the surface 116 of the hollow portion 112 of the supporting structure 106 to provide electrical connection to other devices. The connecting pad 118 on the supporting structure 106 is higher than the electronic component 126. The connecting pad is a surface mounting pad, a die-bonding pad, or a combination thereof. Since the connecting pad 118 and the electronic component 126 are on the same side, the circuit lines between the connecting pad 118 and the electronic component 126 do not penetrate the supporting structure 106, thereby simplifying circuit layouts.

Additionally, a filling material 120 can be formed on a surface of the electronic component 126 according to needs to protect the electronic component 126. As shown in FIG. 1B, the filling material can fully or partially fill the hollow portion 112. The filling material is glue, sealant, packaging materials, paint, plastic, or a combination thereof.

As shown in FIG. 1C, a passive component 122 can be formed on another surface 124 of the communication module 100, further reducing the size thereof. The passive component 122 electrically connects to the electronic component 126 or the connecting pad 118. The surface 124 corresponds to the surface 116 of the hollow portion 112 in FIG. 1B. For example, the surface 116 can be opposite to the surface 124. The passive component 122 includes oscillators, crystals, filters, unbalanced to balanced converters, inductors, capacitors, resistors, or a combination thereof.

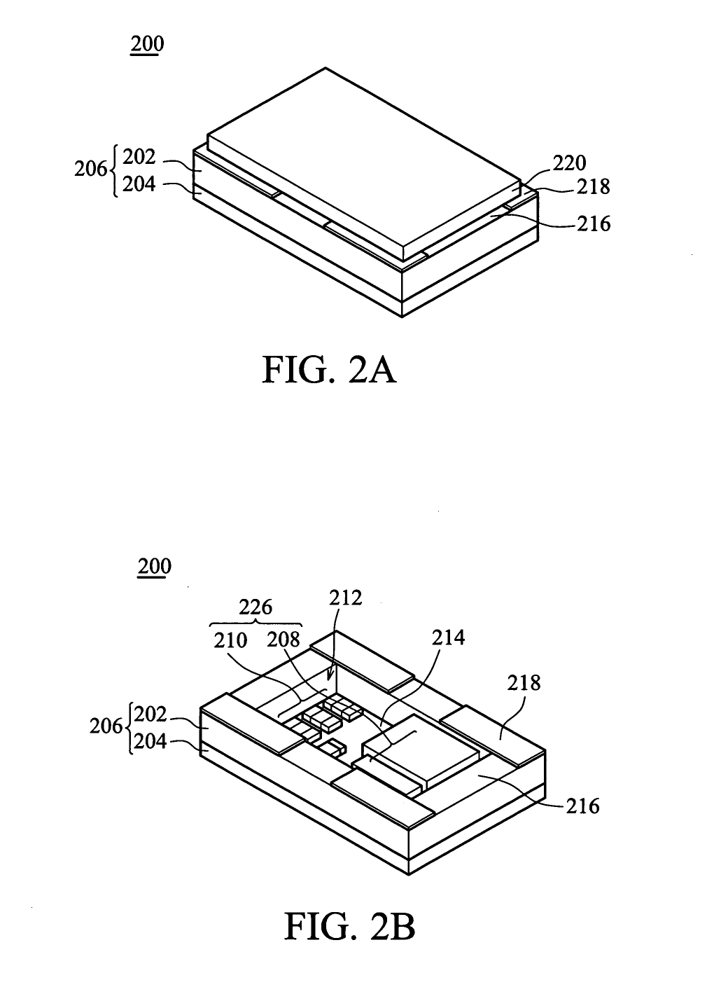

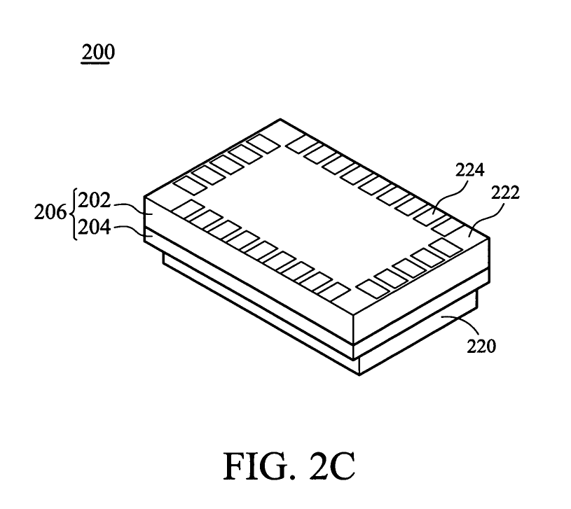

FIG. 2A is a schematic view of another embodiment of a communication module 200 of the invention. FIG. 2B is a schematic view of the communication module 200 of FIG. 2A without showing crystal 220. FIG. 2C is a schematic view showing a connecting structure 224 formed on another surface 222 of the communication module 200 of FIG. 2A. The difference is that the passive component such as oscillator or crystal covers the active component such that the size of communication module is significantly reduced.

As shown in FIGS. 2A to 2C, the communication module 200 comprises a supporting structure 206, an electronic component 226, a crystal 220, a connecting pad 218, and a connecting structure 224 (connecting pad). The electronic component 226 is disposed in the hollow portion 212 of the supporting structure 206, and the crystal 220 covers the hollow portion 212. The supporting structure 206 comprises surfaces 216 and 222, and the hollow portion 212 is located on the same side as the surface 216. The surfaces 216 and 222 correspond to each other. In an embodiment, the supporting structure 206 is formed by at least two substrates 202 and 204. The substrate 202 comprises the surface 216 and the hollow portion 212. The substrate 204 comprises the surface 222, and a bottom surface 214 of the hollow portion 212 is a partial surface of the substrate 204.

The electronic component 226 includes an active component 208, a passive component 210, or both. The active component 208 and the passive component 210 are as described in the previous embodiment, and explanation thereof is omitted. The crystal 220 in the embodiment can be the same as that disclosed in Taiwan patent publication No. 20041271, Japan patent No. 2001-308640, or China patent publication No. 1520028, or others.

The connecting pad 218 is formed on the surface 216 of the supporting structure 206 to electrically connect the crystal 220 and the electronic component 226. The connecting pad 218 on the supporting structure 206 is higher than the electronic component 226. In this embodiment, the connecting pad 218 corresponds to the connecting structure of the crystal 220. The connecting pad 218 is a spherical pad, a wave solder pad, a flip-clip pad, a surface mounting pad, a die-bonding pad, or a combination thereof.

The connecting structure 224 is formed on another surface 222 of the supporting structure 206, and connected to the electronic component 226, the crystal 220, and the connecting pad 218. The connecting structure 224 provides electrical connection between the communication module 200 and the other devices. The connecting structure 224 is a pin, a spherical pad, a wave solder pad, a flip-clip pad, a connecting line, a surface mounting pad, a die-bonding pad, or a combination thereof.

Additionally, in the embodiment, the crystal 220 covers the hollow portion 212, although the embodiment is not limited thereto. The crystal 220 can partially cover the hollow portion 212 and expose some of the electronic component 226. In some embodiments, the crystal 220 can be changed to other passive components according to different requirements.

In the embodiment, since the electronic component 226 is covered by the crystal 220, a shielding layer formed on a surface of the crystal 220 directly prevents EMI with the communication module 200.

Additionally, since the electronic components are embedded in the hollow portion of the supporting structure, and the connecting pad on the same side is higher than the electronic component, the circuit lines therein do not penetrate the supporting structure. The communication module is connected to other devices via the connecting pad on the same side. Thus, the volume of the communication module is significantly reduced as compact as possible.

Moreover, since the crystal is disposed on a surface of the supporting structure, and covers electronic components such as Bluetooth chips or memory chips. The metal surface of the crystal acts as an EMI shield, such that the invention does not require extra shielding from a metal layer, thereby reducing manufacturing costs.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A communication module comprising:
at least one supporting structure comprising a first surface and at least one hollow portion;
at least one first electronic component disposed in the hollow portion; and
at least one connecting pad disposed on the first surface and electrically connected to the first electronic component.

2. The communication module as claimed in claim 1, wherein the connecting pad and the first electronic component are disposed on the same side of the supporting structure.

3. The communication module as claimed in claim 1, wherein the connecting pad is disposed on the supporting structure at a position higher than the first electronic component.

4. The communication module as claimed in claim 1, wherein the connecting pad is a spherical pad, a wave solder pad, a flip-clip pad, a surface mounting pad, or a die-bonding pad.

5. The communication module as claimed in claim 1, wherein the first electronic component includes at least one active component, at least one passive component, or both.

6. The communication module as claimed in claim 5, wherein the active component includes Bluetooth chips or memory chips.

7. The communication module as claimed in claim 5, wherein the passive component includes oscillators, crystals, filters, unbalanced to balanced converters, inductors, capacitors, or resistors.

8. The communication module as claimed in claim 1, further comprising at least one circuit line, embedded in the supporting structure and connecting the connecting pad and the first electronic component.

9. The communication module as claimed in claim 8, wherein the circuit line comprises at least one passive component.

10. The communication module as claimed in claim 1, further comprising a filling material for covering the first electronic component.

11. The communication module as claimed in claim 10, wherein the filling material is glue, sealant, packaging materials, paint, plastic, or a combination thereof.

12. The communication module as claimed in claim 1, further comprising a second electronic component, disposed in the hollow portion or on a second surface of the supporting structure.

13. The communication module as claimed in claim 1, further comprising a shielding layer embedded in or disposed on the supporting structure.

14. The communication module as claimed in claim 1, wherein the supporting structure is a ceramic, a low dielectric constant material, a glass fiber, an organic compound, or a combination thereof.

15. The communication module as claimed in claim 1, wherein the supporting structure further comprises:
a first substrate surrounding the hollow portion and comprising the first surface; and
a second substrate disposed under the first substrate, wherein a bottom surface of the hollow portion is a partial surface of the second substrate.

16. The communication module as claimed in claim 15, wherein the first substrate and the second substrate are formed by the same materials or the different materials.

17. The communication module as claimed in claim 1, wherein the communication module is a Bluetooth module.

18. The communication module as claimed in claim 1, wherein the connecting pad electrically connects the first electronic component to the other devices.

19. The communication module as claimed in claim 1, further comprising:
at least one second electronic component, disposed on the first surface, covering the hollow portion, and connected to the connecting pad; and
at least one connecting structure, disposed on a second surface of the supporting structure and connected to the first electronic component and the second electronic component.

20. The communication module as claimed in claim 19, wherein the connecting structure is a pin, a spherical pad, a wave solder pad, a flip-clip pad, a connecting line, a surface mounting pad, or a die-bonding pad.
